(19) United States
(12) Patent Application Publication
(10) Pub. No.: US 2016/0223808 A1
(43) Pub. Date: Aug. 4, 2016

(54) SYSTEMS AND METHODS FOR SELECTING AN OPERATING VOLTAGE OF A DISPLAY APPARATUS

(71) Applicant: Pixtronix, Inc., San Diego, CA (US)

(72) Inventor: Patrick Forrest Brinkley, San Mateo, CA (US)

(21) Appl. No.: 14/790,619

(22) Filed: Jul. 2, 2015

Related U.S. Application Data
(60) Provisional application No. 62/109,944, filed on Jan. 30, 2015.

(51) Int. Cl. G02B 26/02; B81B 7/02

(52) U.S. Cl. CPC G02B 26/02; B81B 7/02; B81B 2201/047; B81B 2207/053; B81B 2207/017

(57) ABSTRACT

This disclosure provides systems, methods and apparatus for selecting an operating voltage of a display apparatus. In one aspect, a display apparatus can include a plurality of a plurality of image-forming display elements and optically inactive display elements. The image-forming display elements and optically inactive display elements can have a common architecture. Each optically inactive display element can have one or more design parameters that are different from a corresponding design parameter of the image-forming display elements. At least one test voltage can be applied to the optically inactive display elements, and their shutter response times can be measured. An operating voltage for the display apparatus can be selected based on the measured response times.

### CROSS-REFERENCE TO RELATED APPLICATIONS

This patent application claims priority to U.S. Provisional Patent Application No. 62/109,944 entitled “SYSTEMS AND METHODS FOR SELECTING AN OPERATING VOLTAGE OF A DISPLAY APPARATUS,” filed Jan. 30, 2015, assigned to the assignee hereof and hereby expressly incorporated by reference herein.

### TECHNICAL FIELD

This disclosure relates to the field of imaging displays, and to light modulators incorporated into imaging displays.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

EMS-based display apparatus have been proposed that include display elements that modulate light by selectively moving a light-blocking component into and out of an optical path through an aperture defined through a light-blocking layer. Some of the display elements may actuate at different voltage levels due to non-uniformity in the manufacturing process. Incorporating optically inactive test pixels can help in the selection of a lower operating voltage to save power.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus. The apparatus can include a first substrate and an array of image-forming display elements positioned on the first substrate to form an image-forming region. Each image-forming display element can include a shutter. The apparatus also can include a plurality of optically inactive display elements positioned on the first substrate. Each optically inactive display element can include a shutter. Each image-forming display element and each optically inactive display element can have a common architecture. Each image-forming display element can be substantially identical to each other image-forming display element. Each optically inactive display element can have at least one design parameter that differs from a corresponding design parameter of the image-forming display elements. The at least one design parameter of a first optically inactive display element can differ from the at least one design parameter of a second optically inactive display element.

In some implementations, each image-forming display element and each optically inactive display element can include at least one actuator including a load beam attached to its respective shutter and a drive beam. In some implementations, for each optically inactive display element, the at least one design parameter that differs from a design parameter of the image-forming display elements is a separation distance between the respective load beam and a distal end of the respective drive beam. In some implementations, for each optically inactive display element, the at least one design parameter that differs from a design parameter of the image-forming display elements is an angle of the respective drive beam relative to the respective load beam. In some implementations, for each optically inactive display element, the at least one design parameter that differs from a design parameter of the image-forming display elements is a length of the respective drive beam. In some implementations, for each optically inactive display element, the at least one design parameter that differs from a design parameter of the image-forming display elements is a length of the respective load beam.

In some implementations, each image-forming display element and each optically inactive display element can include a respective transistor. For each optically inactive display element, the at least one design parameter that differs from a design parameter of the image-forming display elements can be a channel width of the respective transistor. In some implementations, for each optically inactive display element, the at least one design parameter that differs from a design parameter of the image-forming display elements is a width of the respective shutter.

In some implementations, the apparatus can include a second substrate opposed to the first substrate. For each optically inactive display element, the at least one design parameter that differs from a design parameter of the image-forming display elements can be a separation distance between a surface of the respective shutter and a surface of the second substrate. In some implementations, the apparatus can include at least one of a photodiode or a camera capable of measuring a response time to an applied voltage for the respective shutters of each optically inactive display element.

In some implementations, the apparatus can include a controller configured to select an operating voltage for the apparatus. The controller can be further configured to select the operating voltage for the apparatus based on a measured response to a single voltage applied to each optically inactive display element. The controller also can be further configured to select the operating voltage for the apparatus based on a measured response to a range of voltages applied to each optically inactive display element. In some implementations, the optically inactive display elements can be positioned outside of the image-forming region. In some implementations, the optically inactive display elements can be positioned within the image-forming region.

In some implementations, the apparatus can include a display and a processor capable of communicating with the display. The processor can be capable of processing image data. The apparatus also can include a memory device capable of communicating with the processor. In some implementations, the apparatus can include a driver circuit capable of sending at least one signal to the display and a controller capable of sending at least a portion of the image data to the driver circuit. In some implementations, the apparatus can include an image source module capable of sending the image data to the processor. The image source module can include at least one of a receiver, transceiver, and transmitter. In some implementations, the apparatus includes an input device capable of receiving input data and communicating the input data to the processor.

Another innovating aspect of the subject matter described in this disclosure can be implemented in a system for calibrating a display apparatus. The system can include a controller configured to transmit to each of a plurality of optically inactive display elements positioned over a display element substrate a signal causing a shutter associated with each of the plurality of optically inactive display elements to move into a closed position. The system can include a backlight positioned behind the display element substrate. The system can include an optical detection system configured to measure a response time for each of the optically inactive display elements.

In some implementations, the optical detection system can include at least one of a photodiode or a camera. In some implementations, the display element substrate can include an array of image-forming display elements positioned on the first substrate to form an image-forming region. The plurality of optically inactive display elements can be positioned outside of the image-forming region.

In some implementations, each image-forming display element and each optically inactive display element can have a common architecture. Each image-forming display element can be substantially identical to each other image-forming display element. Each optically inactive display element can have at least one design parameter that differs from a corresponding design parameter of the image-forming display elements. The at least one design parameter of a first optically inactive display element can differ from the at least one design parameter of a second optically inactive display element.

In some implementations, the controller can be configured to select an operating voltage for the apparatus. In some implementations, the controller can be configured to select the operating voltage for the apparatus based on a measured response to a range of voltages applied to each optically inactive display element. In some implementations, the apparatus can include a memory element configured to store a lookup table indicating operating voltages suitable for a range of measured response times of optically inactive display elements.

Another innovating aspect of the subject matter described in this disclosure can be implemented in a method for manufacturing a display apparatus. The method can include forming, according to a first set of design parameters, an array of image-forming display elements between a front substrate and a rear substrate to form an image-forming region, each image-forming display element including a shutter. The method can include forming a plurality of optically inactive display elements between the front substrate and the rear substrate. Each optically inactive display element can include a shutter and can be formed according to a respective set of design parameters that includes at least one design parameter that differs from a corresponding design parameter of the first set of design parameters. The method can include applying at least one voltage to each of the plurality of optically inactive display elements. The method can include evaluating a voltage response for each optically inactive display element, based on the at least one applied voltage. The method can include selecting an operating voltage for the display apparatus, based on the voltage response evaluation for each optically inactive display element.

Another innovating aspect of the subject matter described in this disclosure can be implemented in a method for calibrating a display apparatus. The method includes applying, by a controller, at least one voltage to each of a plurality of optically inactive display elements positioned on a first substrate of the display apparatus. The optically inactive display elements share a common architecture with a plurality of image-forming display elements positioned on the first substrate. Each image-forming display element is substantially identical to each other image-forming display element. Each optically inactive display element has at least one design parameter that differs from a corresponding design parameter of the image-forming display elements. The at least one design parameter of a first optically inactive display element differs from the at least one design parameter of a second optically inactive display element. The method includes evaluating a voltage response for each optically inactive display element, based on the at least one applied voltage. The method includes selecting an operating voltage for the display apparatus, based on the voltage response evaluation for each optically inactive display element.

In some implementations, the method can include applying, by the controller, a range of voltages to each of the plurality of optically inactive display elements positioned on a first substrate of the display apparatus. The method can include evaluating voltage responses for each optically inactive display element, based on the range of applied voltages. The method can include selecting the operating voltage for the display apparatus, based on the voltage responses evaluations for each optically inactive display element. In some implementations, the method also can include illuminating the first substrate. Evaluating the voltage response for each optically inactive display element can include measuring, by an optical detection system, a response time for each of the optically inactive display elements.

In some implementations each image-forming display element and each optically inactive display element can include at least one actuator including a load beam attached to its respective shutter and a drive beam. In some implementations, for each optically inactive display element, the at least one design parameter that differs from a design parameter of the image-forming display elements can be a separation distance between the respective load beam and a distal end of the respective drive beam. In some implementations, for each optically inactive display element, the at least one design parameter that differs from a design parameter of the image-forming display elements is an angle of the respective drive beam relative to the respective load beam.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows an example display apparatus incorporating image-forming display elements and optically inactive display elements.

FIG. 4 shows a flow chart of an example process for manufacturing a display apparatus.

FIG. 5A shows a first example lookup table for selecting an operating voltage of a display apparatus.

FIG. 5B shows a second example lookup table for selecting an operating voltage of a display apparatus.

FIG. 6A shows a block diagram of an example system for selecting an operating voltage for a display apparatus.

FIG. 6B shows a perspective view of a portion of the system shown in FIG. 6A.

FIGS. 7A-7C show example optically inactive display elements having various tip gap separations.

FIGS. 8A-8C show example optically inactive display elements having drive beams positioned at various angles.

FIGS. 9A-9C show example optically inactive display elements having shutters of various widths.

FIG. 10 shows a cross-sectional view of an example display apparatus including three optically inactive display elements having various cell gaps.

FIGS. 11A and 11B show system block diagrams of an example display apparatus that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

The dimensions of display elements in a display apparatus impact the voltages required to drive the display. Generally, higher drive voltages result in higher power consumption by the display apparatus. Typically, each display element in a display apparatus is fabricated according to a common set of design parameters. Ideally therefore, each display element would be identical to each other display element. However, due to imprecisions in the manufacturing process, some variation in the actual dimensions of the display elements can be expected. These dimensional variations lead to variations in the voltage required to drive each display element. The operating voltage of the display apparatus should be sufficient to drive every display element, or at least the vast majority of display elements. To account for the potential of the variation described above, display apparatus are often driven at higher voltages than are required. Determining appropriate operating voltages for a specific display apparatus based on a characterization of the voltage response of that display apparatus can result in lower power consumption.

To facilitate such a characterization, a display apparatus can include image-forming display elements positioned within an image-forming region of the display apparatus and optically inactive display elements positioned outside of the image-forming region. The optically inactive display elements can share a common architecture with the image-forming display elements, but can include design parameters that differ slightly from those of the image-forming display elements and from each other. Test voltages can be applied to the optically inactive display elements to cause the optically inactive display elements to move into a closed or open position. The voltage responses of the optically inactive display elements can be measured. These measurements can be used to select an operating voltage for the display that will provide a high degree of likelihood that a sufficient number of the image-forming display elements within the display apparatus will function properly, without using excess power.

Particular implementations of the subject matter described in this disclosure can be implemented to realize one or more of the following potential advantages. By incorporating optically inactive display elements into a display apparatus and testing their voltage responses, an appropriate operating voltage for the display apparatus can be selected. As such, some display apparatus may use lower operating voltages than other display apparatus whose nominal design parameters are the same. This can help to save power in some of the display apparatus without sacrificing image quality. In some implementations, the optically inactive display elements may be used to calibrate the operating voltage of the display apparatus over time to account for changes in the characteristics of the display elements that may occur over the lifetime of the display apparatus. In some implementations, the variation in design parameters of the optically inactive display elements can be selected to approximate the variation expected to occur within the image-forming display elements. Thus, the variation across all of the image-forming display elements may be estimated based on a significantly smaller number of optically inactive display elements.

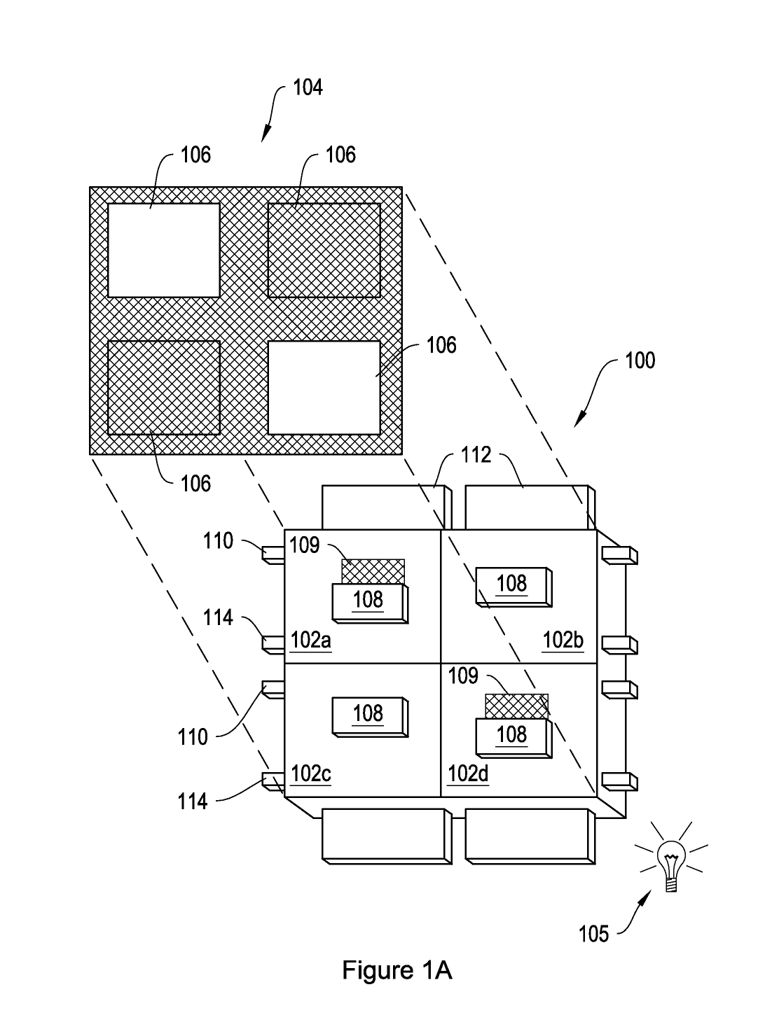

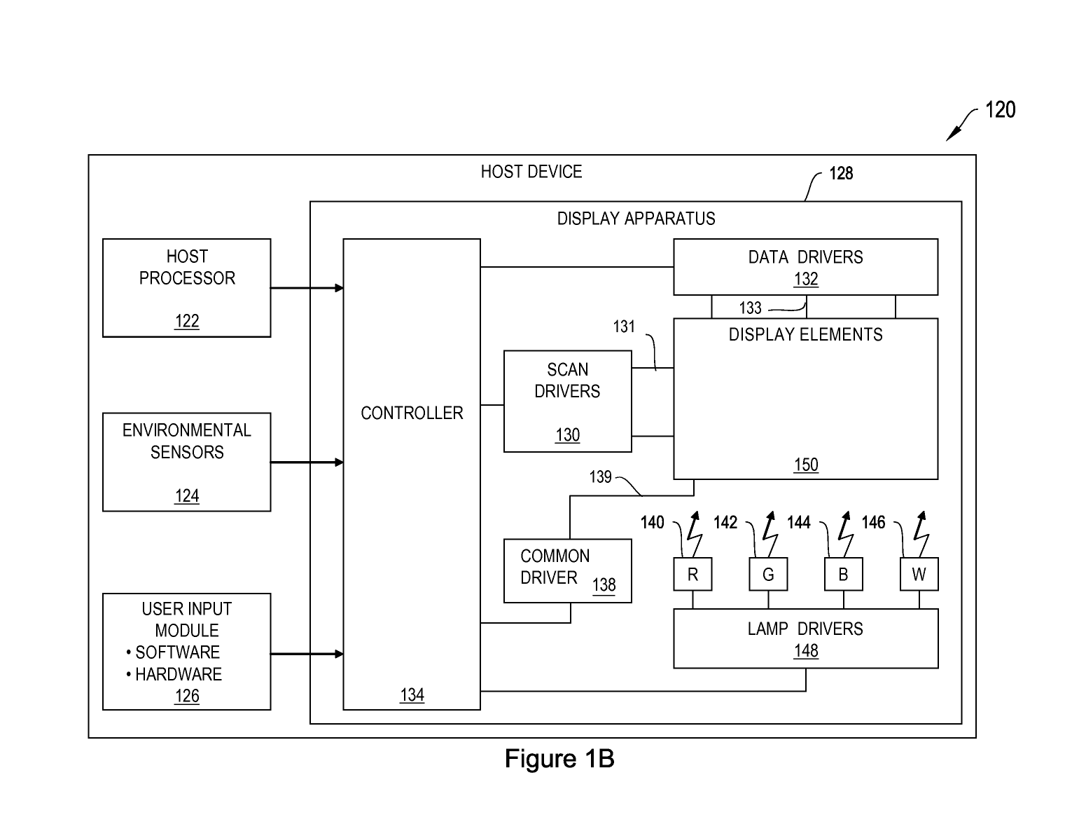

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying only a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for only a certain fraction of the image is loaded to the array of display elements 150. For example, the sequence can be implemented to address only every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

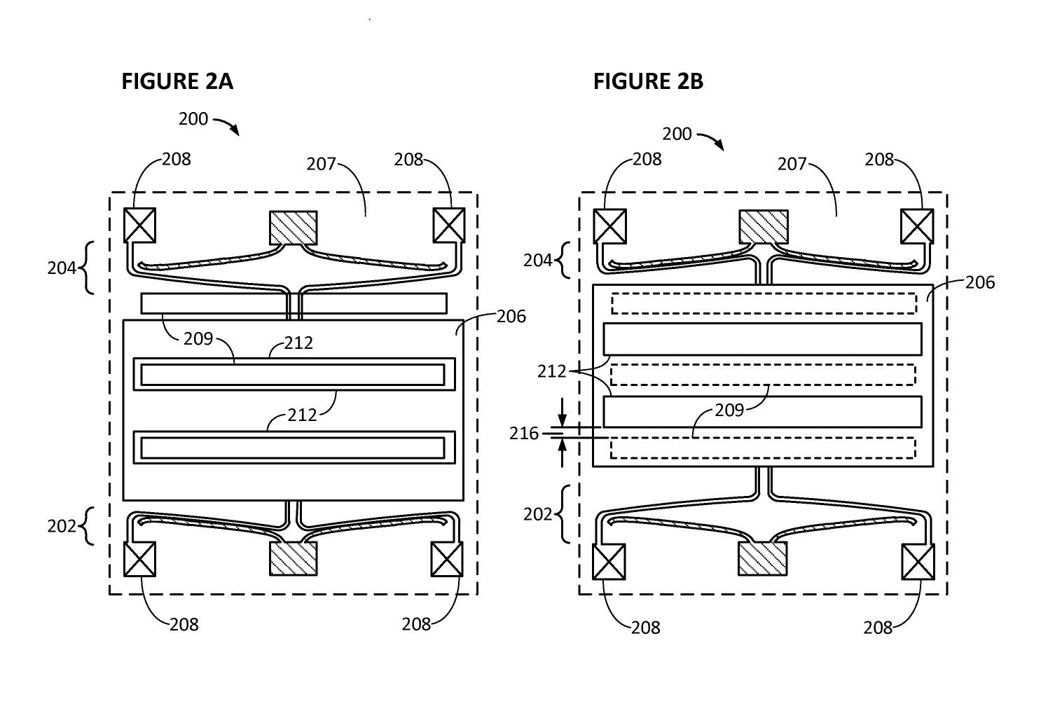

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light-blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have only a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light-blocking portions of the shutter 206 can be designed to overlap the edges of the apertures 209. FIG. 2B shows an overlap 216, which in some implementations can be predefined, between the edge of light-blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

In some implementations, the actuators 202 and 204 and the shutter 206 can all be fabricated in an integrated process from the same materials. For example, in some implementations, a multi-level mold made of sacrificial material, such as a photodefinable resin, is formed using photolithography. The mold includes surfaces that are parallel to the primary plane of the mold, and sidewalls that are normal to the primary plane of the mold. After the mold is defined, one or more layers of structural material, such as metals or semiconductors, are deposited over the mold in one or more conformal deposition processes, including, e.g., sputtering, physical vapor deposition (PVD), electroplating, chemical vapor deposition (CVD), plasma-enhanced chemical vapor deposition (PECVD), or atomic level deposition (ALD). Specific examples of suitable materials include, without limitation, amorphous silicon (a-Si), titanium (Ti), and aluminum (Al). The structural materials are then etched using one or more etch processes. In some implementations, an anisotropic etch is used to remove undesired portions of the structural material deposited on surfaces of the mold that are parallel to the primary plane of the mold, while leaving structural material on the sidewalls. This material on the sidewalls forms the beams of the actuators 202 and 204. It also forms the vertical surfaces of the anchors 208. The mold is then removed through a release process, freeing the remaining components to move.

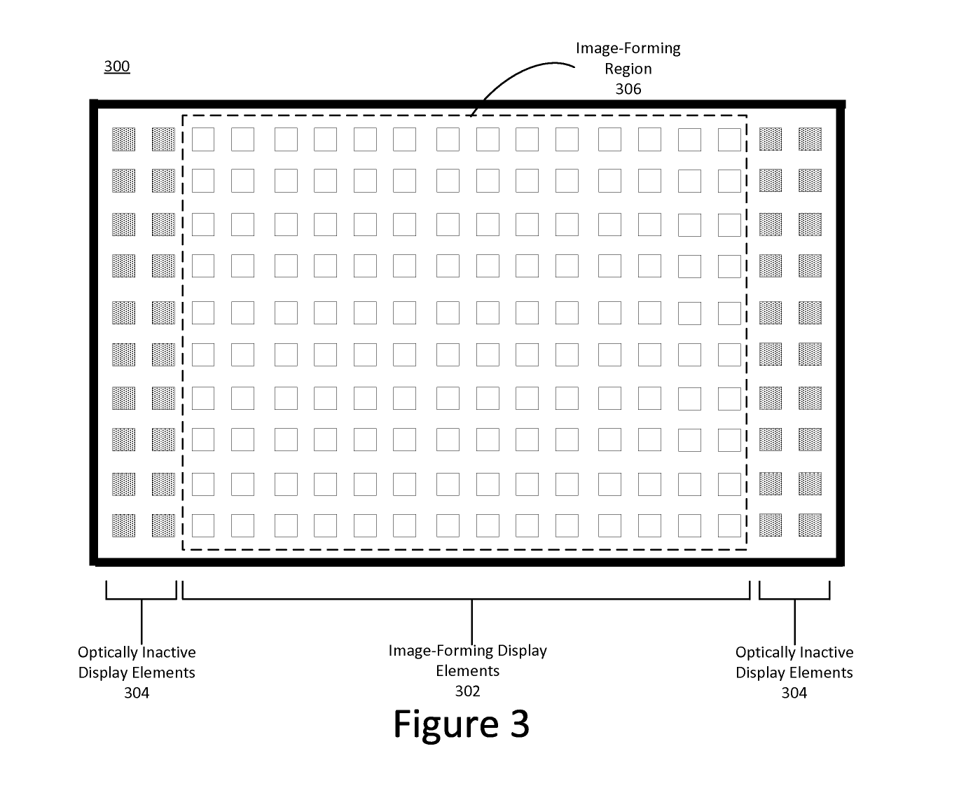

FIG. 3 shows an example display apparatus 300 incorporating image-forming display elements 302 and optically inactive display elements 304. The optically inactive display elements 304 do not contribute to the formation of an image, but can be used for other purposes, such as testing and calibration, for example, selecting an appropriate operating voltage for the display apparatus 300. For illustrative purposes, the image-forming display elements 302 are arranged in a grid pattern having fourteen columns and ten rows. In an actual display, the array 300 could have hundreds or thousands of rows and/or columns. The image-forming display elements 302 define an image-forming region 306 of a display. In some implementations, each image-forming display element 302 can be implemented as a shutter-based light modulator capable of outputting various intensities of light, as described above in connection with FIGS. 2A and 2B. A controller can determine whether each shutter of the image-forming display elements 302 should be in a light-transmissive or light-obstructing state based on the content of an image to be displayed within the image-forming region 306. The optically inactive display elements 304 are positioned outside of the image forming region 306 so that their presence does not interfere with the formation of images within the image-forming region 306.

In some implementations, the optically inactive display elements 304 can include display elements that have the same general architecture as the image-forming display elements 302. That is, the optically inactive display elements 304 can have substantially the same mechanical structure and control circuitry as the image forming display elements 302. For example, the optically inactive display elements 304 can include components such as shutters, drive beams, load beams, anchors, and electronic circuitry which are similar in shape, function, and arrangement to corresponding components of the image-forming display elements 302. However, each optically inactive display element 304 may have at least one design parameter that differs from a corresponding design parameter of the image-forming display elements 302. For example, the optically inactive display elements 304 may include display elements having, without limitation, differing separation distances between a front portion of their drive beams and load beams (i.e., differing tip gaps), differing drive beam angles, differing shutter widths, differing shutter heights, or differing transistor characteristics.

In some implementations, the optically inactive display elements 304 may include other design parameters that differ from corresponding parameters of the image-forming display elements 302. For example, in some implementations, each optically inactive display element 304 and each image-forming display element 302 may include at least one transistor. The image-forming display elements 302 may have transistors whose feature sizes (e.g., channel widths) are all substantially identical, while the optically inactive display elements 304 may include transistors having a range of sizes for their channels or other features.

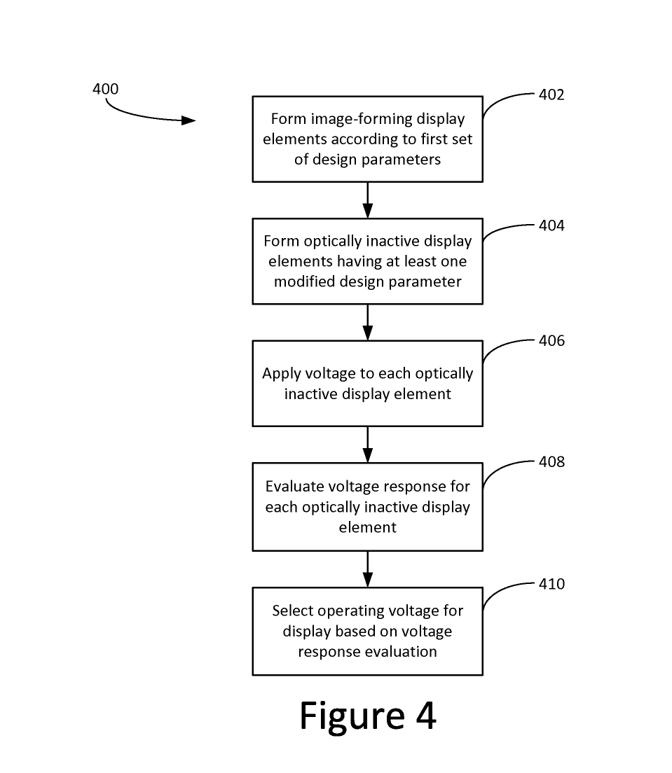

As discussed further below in relation to FIG. 4, the voltage response of the optically inactive display elements can be evaluated to determine appropriate operating voltages for the display apparatus as a whole. In some implementations, positioning the optically inactive display elements 304 on either side of the image-forming region 306 can help to evaluate display element voltage response variations that may be spatially dependent. For example, some voltage response variations may be correlated with the position of a particular display element within the display 300. By including optically inactive display elements 304 on both sides of the image-forming region 306, rather than on only one side, such spatially dependent variations have a higher probability of being present in the optically inactive display elements 304. Therefore, a process that makes use of the optically inactive display elements 304 to select an operating voltage, such as the process described below in connection with FIG. 4, is more likely to compensate for these spatially dependent variations.

In some other implementations, optically inactive display elements 304 can be included within the image forming region 306. For example, if the display element density of the display apparatus 300 is sufficiently high, a viewer may not be able to discern the presence of optically inactive display elements 304 within the image-forming region 306. As a result, positioning some of the optically inactive display elements 304 within the image-forming region may not negatively impact the quality of images produced by the display apparatus 300.

FIG. 4 shows a flow chart of an example process 400 for manufacturing a display apparatus. In brief overview, the process 400 includes forming image-forming display elements according to a first set of design parameters (stage 402). Optically inactive display elements having at least one modified design parameter are formed (stage 404). A voltage is applied to each optically inactive display element (stage 406). The voltage response of the optically inactive display elements is evaluated (stage 408). An operating voltage for the display is selected based on the voltage response evaluation (stage 410).

The process 400 includes forming a plurality of image-forming display elements according to a first set of design parameters (stage 402). The image-forming display elements can be formed within an image-forming region, such as the image-forming region 306 shown in FIG. 3. All of the design parameters can be identical for each image forming display element. Ideally, the resulting image-forming display elements will be substantially identical. However, due to imperfections that result from the manufacturing process, some variation in the image-forming display elements is generally expected. These variations can impact the operating voltage required to actuate the shutter of each image-forming display element. Because the distribution and/or degree of display element variations may differ in each display apparatus, it can be difficult to select appropriate operating voltages for each display apparatus on an individual basis.

The process 400 includes forming optically inactive display elements (stage 404). At least some of the optically inactive display elements have at least one design parameter that differs from a corresponding design parameter of the image-forming display elements. For example, the optically inactive display elements can include variations in the tip gap, drive beam angle, drive beam length, load beam length, shutter height, or transistor channel width. In some implementations, the optically inactive display elements can be formed outside of the image-forming region of the display, such that they will not interfere with the formation of images within the image-forming region. In other implementations, some of the optically inactive display elements can be formed within the image-forming region, although they will not contribute to the formation of an image.

In some implementations, the optically inactive display elements may be formed simultaneously with the image-forming display elements. For example, the image-forming display elements and the optically inactive display elements may both be formed by depositing one or more layers of material over a mold formed over a substrate. The optically inactive display elements can be formed from the same layers of material used to form the image-forming display elements. The design parameters of the optically inactive display elements can be varied, for example, by altering the dimensions of the mold in the regions where the optically inactive display elements are to be formed accordingly. In some other implementations, the process used to fabricate the optically inactive display elements may be separate from the process used to fabricate the image-forming display elements. For example, the optically inactive display elements may be formed before or after the formation of the image-forming display elements.

In some implementations, other circuitry associated with the display elements may also be formed. For example, each display element can include at least one transistor configured to apply an actuation voltage to its respective display element. The transistors associated with the optically inactive display elements can be formed using different design parameters, such as channel widths, than those used to form the transistors associated with the image-forming display elements. In some implementations, the design parameters of the components of each display element can be altered by altering the feature sizes of a photoresist mask used in the manufacturing process. For example, a photoresist mask can be deposited over one or more layers of structural, semiconductive, and/or conductive material. The mask can then be patterned to serve as an etch mask for the structural, semiconductive, and/or conductive material. Altering the feature sizes of the mask in the regions where the optically inactive display elements are formed can allow a subsequent etching step to result in optically inactive display elements whose design parameters are different from the design parameters of the image-forming display elements.

The process 400 includes applying a voltage to each optically inactive display element (stage 406). In some implementations, the voltage can be selected to be equal to a nominal operating voltage of the display. In other implementations, a different voltage may be applied. In some implementations, a range of voltages, rather than a single voltage, can be applied to the optically inactive display elements. The voltage can be applied to the optically inactive display elements by drivers included within the display apparatus. For example, instructions may be sent to the drivers 130, 132, and 138 shown in FIG. 1B to cause an actuation voltage to be applied to the optically inactive display elements.

The process 400 includes evaluating a voltage response of the optically inactive display elements (stage 408). In some implementations, the voltage response can be measured by an optical detection system, such as a photodiode array or a high-speed camera.

In some implementations, the evaluation of the voltage response is a shutter response time. The shutter response time can be calculated as the time it takes for an optically inactive display element to reduce its light output below a threshold (or increase its light output over a threshold) value after the actuation voltage is applied. In implementations in which a range of actuation voltages are applied to the optically inactive display elements, the shutter response time for each optically inactive display element can be measured separately for each test voltage. The shutter response times can then be stored in a memory. In some implementations, the test voltage may be applied (stage 406) to all of the optically inactive display elements simultaneously. This can allow for the shutter response times for each of the optically inactive display elements to be measured (stage 408) at the same time, thereby reducing the amount of time required to complete the process 400.

In some implementations, the voltage response can be measured in terms of the number or percentage of optically inactive display elements that change state in less than a threshold amount of time. In some implementations, this can be determined by comparing the individual shutter response times of the display elements to the threshold. In some implementations, the number is determined by obtaining an instantaneous count at the threshold time of the number of optically inactive display elements that have fully actuated. The threshold time can be the minimum acceptable actuation time for the display apparatus. In this example, it is not necessary to determine the specific actuation time for each optically inactive display element. A binary value corresponding to whether each optically inactive display element is able to actuate within the threshold amount of time can then be stored in a memory. Alternatively, a total amount of actuating display elements is stored.

The process 400 includes selecting an operating voltage for the display based on the voltage response evaluation (stage 410). In some implementations, the voltage response evaluation results may be compared to values stored in a lookup table.

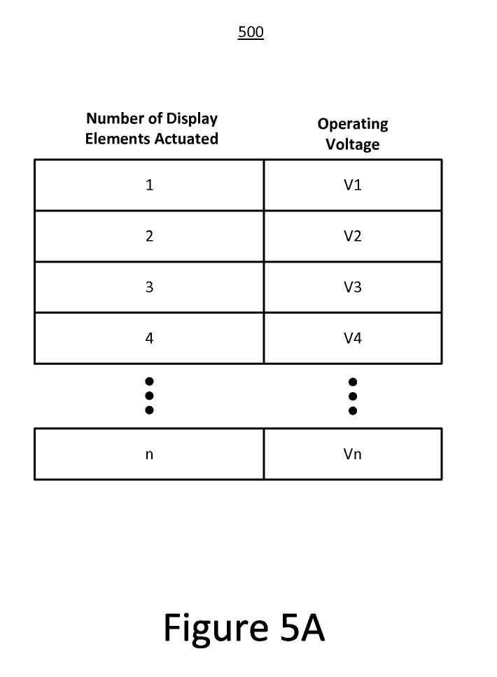

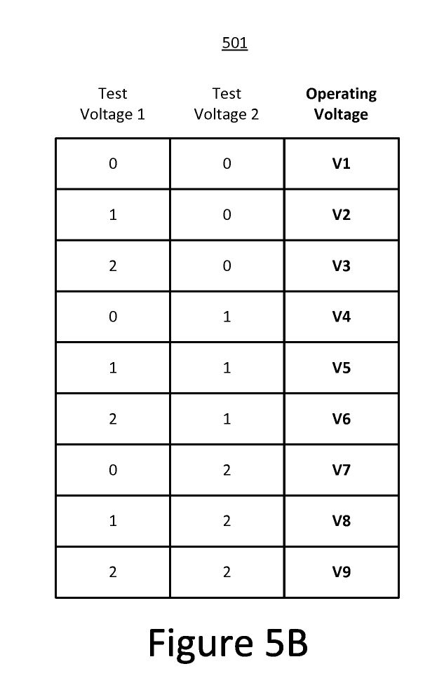

FIG. 5A shows a first example lookup table 500 for selecting an operating voltage of a display apparatus. The table 500 includes n rows and two columns, where n is the number of optically inactive display elements included in the display apparatus.

Using the table 500, the operating voltage is selected based on the number of optically inactive display elements that actuate sufficiently fast in response to a test voltage. For example, if it is determined that four of the optically inactive display elements actuated within the threshold amount of time, then V4 can be selected as the operating voltage of the display. In some implementations, the values stored in the operating voltage column (such as V4) can be dimensionless weighting factors that can be multiplied by the applied test voltage to determine the operating voltage for the display. In some implementations, the stored values may be specific operating voltages. In other implementations, the lookup table may be implemented in other forms.

FIG. 5B shows a second example lookup table 501 for selecting an operating voltage of a display apparatus. The table 501 includes nine rows and three columns. The leftmost column represents the number of optically inactive display elements actuated at a first test voltage, and the center column represents the number of optically inactive display elements actuated at a second test voltage. For illustrative purposes, the table 501 only includes entries for a display having zero, one, or two optically inactive display elements that fully actuate in response to the test voltages. In practice, a display apparatus may have tens, hundreds, or thousands of optically inactive display elements, and the lookup table 501 may have thousands or millions of rows. In some implementations, the table 501 can be stored in a computer memory as a data structure such as an array.

Using table 501, the operating voltage can be selected as the value in the rightmost column corresponding to the row whose entries match that of the display apparatus under test. For example, if two optically inactive display elements actuate in response to the first test voltage and one optically inactive display element actuates in response to the second test voltage, then the operating voltage for the display apparatus can be selected as V6. In some implementations, the table 501 may have additional columns corresponding to additional test voltages.

Tables 500 and 501 can be populated based on historical data collected from one or more display apparatus that have been manufactured in the past. For example, in some implementations, display apparatus may be tested at a regular frequency during the course of manufacturing many display apparatus (e.g., one out of every thousand display apparatus may be tested to generate the lookup tables 500 and 501). Such a scheme can be used to update the lookup tables 500 and 501 over time, which can help to account for variations in display elements caused by imperfections in the manufacturing process that may also change over time.

Image quality can be impacted by the percentage of image-forming display elements that are able to actuate within the threshold time. In general, a display apparatus incorporating a larger percentage of image-forming display elements that are able to actuate within the threshold time can produce higher quality images than a display apparatus having a smaller percentage of image-forming display elements that can actuate within the threshold time. However, in some implementations, sufficient image quality may be obtained with less than 100% of the image-forming display elements actuating fully within the threshold time. For example, it may only be necessary for at least 95% of the image-forming display elements to fully actuate within the threshold time. In other implementations, it may be necessary for more than 96%, more than 97%, more than 98% or more than 99% of the image-forming display elements to actuate within the threshold time.

In some implementations, a lookup table, such as the lookup table 500 or the lookup table 501, may be generated by determining a correlation between the number of optically inactive display elements that actuate fully within a threshold time and the operating voltage sufficient to achieve a predetermined image quality from the image-forming display elements. For example, a display apparatus may be tested at a range of voltages to determine the minimum operating voltage at which a desired percentage of the image-forming display elements actuate within the threshold amount of time. The optically inactive display elements of the display apparatus can then be tested to determine the number of optically inactive display elements that actuate fully within the threshold time for a given test voltage level.

In some implementations, many display apparatus may be tested in this way, such that a correlation between the minimum operating voltage and the number of optically inactive display elements that actuate in response to a test voltage can be determined. In some implementations, the correlation can be determined using statistical analysis techniques, such as linear or polynomial regression. In other implementations, a computer model of the test data may be used to determine the correlation between minimum operating voltages and voltage response of optically inactive display elements to a test voltage. This information can then be stored in the form of a lookup table. The minimum operating voltage of a display apparatus can then be estimated based on the voltage response of its optically inactive display elements by referring to the lookup table, as discussed above. This can allow each display apparatus to have an operating voltage that is selected individually, so that each display apparatus operates at the lowest voltage likely to produce images of a sufficient quality.

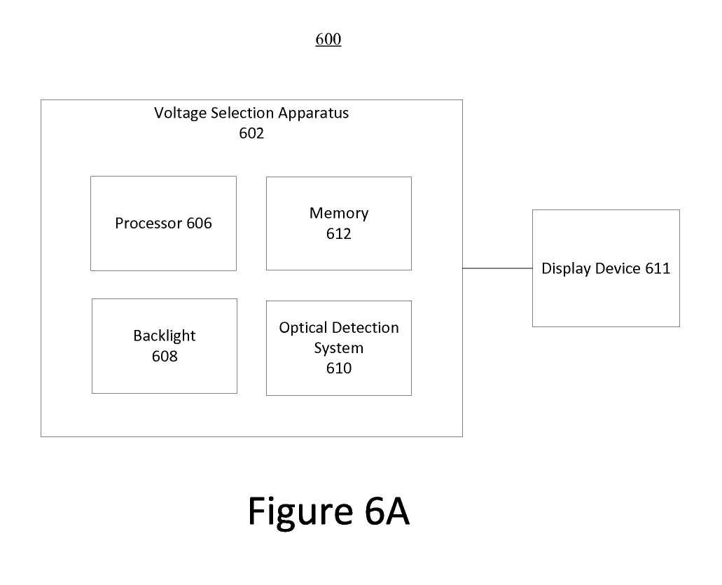

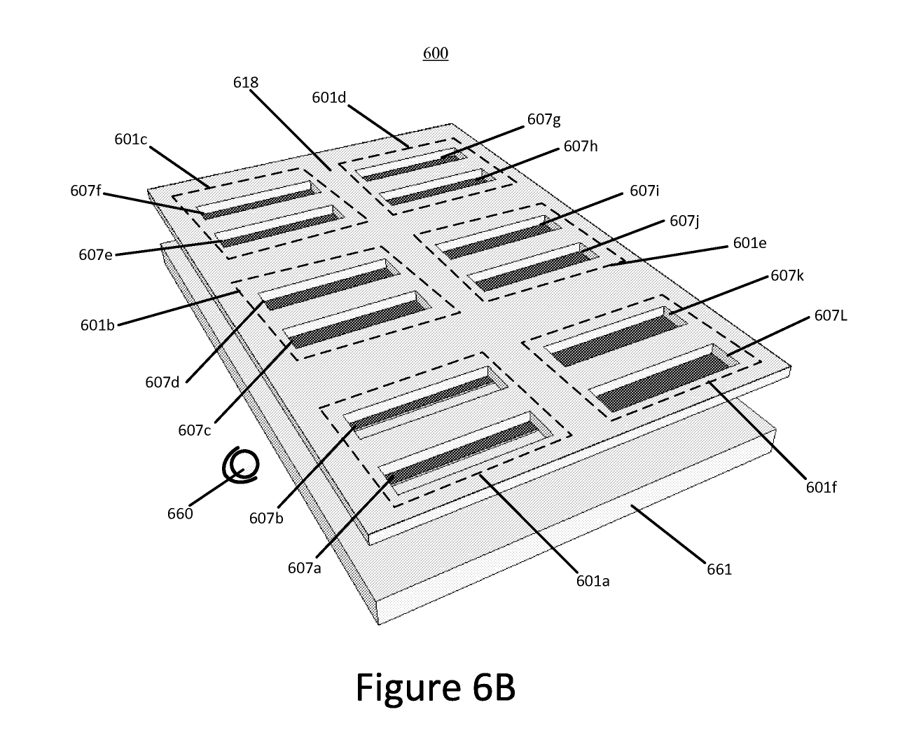

FIG. 6A shows a block diagram of an example system 600 for selecting an operating voltage for a display apparatus. FIG. 6B shows a perspective view of a portion of the system 600 shown in FIG. 6A. The system 600 includes a voltage selection apparatus 602 which includes a processor 606, a backlight 608, an optical detection system 610, and memory 612. The voltage selection apparatus 600 communicates with a display apparatus 611.

The voltage selection apparatus 602 can be used to select an operating voltage for the display apparatus based on the voltage responses of a plurality of optically inactive display elements. For example, the system 600 can carry out steps 406-410 of the process 400 shown in FIG. 4. In some implementations, the voltage selection apparatus 602 can receive a partially formed display apparatus 611. The partially formed display apparatus 611 may include a substrate on which a plurality of display elements have been fabricated. The display elements can include image-forming display elements within an image-forming region, as well as optically inactive display elements positioned outside of the image-forming region. Other components, such as the drivers 130, 132, and 138, and the controller 134 shown in FIG. 1B, may also be included in the partially formed display apparatus 611.

As shown in FIG. 6B, the display apparatus 611 can include a light blocking layer 618 positioned over a plurality of optically inactive display elements 601a-601f (generally referred to as optically inactive display elements 601). The optically inactive display elements 601 are shown in FIG. 6B with broken lines because they are obstructed by the optically inactive light blocking layer 618. Each of the optically inactive display elements 601 is associated with a respective pair of the apertures 607a-607l formed through the light blocking layer 618. Also shown in FIG. 6B is a light source 660 and a light guide 661, which together form the backlight 608. The backlight is positioned below the display elements 601 and is substantially parallel with the light blocking layer 618. For illustrative purposes, the optical detection system 610, memory 612, and processor 606 are not shown in FIG. 6B. In practice, the optical detection system 610 can be positioned on the side of the light blocking layer opposite the backlight 608. This arrangement can allow the optical detection system 610 to detect a presence or absence of light passing through the apertures 607a-607l formed through the light blocking layer 618.

The processor 606 can control the backlight 608 of the voltage selection apparatus to turn on. The backlight can be positioned behind the light blocking layer 618 of the partially formed display apparatus 611, such that the partially formed display apparatus 611 is illuminated from behind the light blocking layer 618 when the backlight 608 is turned on. Light emitted from the backlight 608 can pass through the apertures 607a-607l when the shutters of the respective optically inactive display elements 601 are in an open position, and will be blocked when the respective shutters are in a closed position. When the display apparatus 611 is fully formed, an additional light blocking layer (not shown in FIG. 6B) can be positioned over or beneath the optically inactive display elements 601 to ensure that light does not escape from the display through any of the optically inactive display elements 601, regardless of the state of their shutters.

The processor 606 can then control all of the optically inactive display elements to move into their fully closed positions. In some implementations, the processor 606 can control the optically inactive display elements 601 by communicating with the controller 134 shown in FIG. 1A. For example, in some implementations, the controller 134 may already be coupled to the display apparatus 611. The processor 606 can pass instructions to the controller 134 to cause the controller 134 to cause the drivers 130, 132, and 138 to command each of the optically inactive display elements 601 to move into a fully closed position.

By monitoring the amount of light passing through each optically inactive display element 601, the optical detection system 610 can be used to measure a response time for each optically inactive display element 601. For example, the optical detection system 610 can be a high speed camera or a photodiode array configured to determine the duration of time between the application of an actuation voltage and the time at which a light level falls below a threshold level for each optically inactive display element 601. In some implementations, the optical detection system 610 can determine whether each optically inactive display element 601 actuates fully within a threshold amount of time, rather than determining a particular actuation time for each optically inactive display element 601. For example, the optical detection system 610 can be configured to capture an image after a threshold time has passed since the application of the actuation voltage. The optical detection system 610 can then analyze the captured image to determine whether each optically inactive display element 601 has been actuated within the threshold time. In some implementations, this information can be stored in the memory 612.

FIG. 6B shows the system 600 after the threshold time has elapsed. As shown, the shutters associated with the optically inactive display elements 601b-601f have actuated fully, as indicated by the dark appearance of their respective apertures 607c-607l. However, the shutter associated with the optically inactive display element 601a is only partially actuated, and therefore light is able to pass through the apertures 607a and 607b. In some implementations, the optical detection system 610 can determine which optically inactive display elements 601 have actuated within the threshold time by measuring the light output of the respective apertures 607a-607l after the threshold time has passed. While the example of FIG. 6B has been described with respect to the application of an actuation voltage tending to cause the optically inactive display elements 601 to move into a closed position, in some implementations the applied voltage can tend to cause the optically inactive display elements 601 to move into an open position from a closed position, and the optical detection system 610 can be used to determine the voltage response in a similar manner. In some implementations, the optical detection system 610 can be used to determine the voltage response of the optically inactive display elements 601 by commanding them to move into both closed and open positions. Data for both voltage responses can be stored in the memory 612. For a given optically inactive display element 601, the voltage response observed when the optically inactive display element 601 is commanded to move from an open position into a closed position may differ from the voltage response observed when the optically inactive display element 601 is commanded to move from a closed position into an open position.

The processor 606 can then use the voltage response for the optically inactive display elements to calculate an operating voltage for the display apparatus. In some implementations, the processor 606 can select an operating voltage based on a comparison of the response times to historical data for display apparatus having similar nominal characteristics (e.g., display architecture and resolution). In some implementations, the processor 606 can determine the number of optically inactive display elements 601 that have fully actuated, and can select the operating voltage associated with that number from a lookup table.

The processor 606 can be implemented in a variety of ways. For example, in some implementations, the processor 606 can be defined by computer instructions executing on a general purpose processor. In other implementations, the processor 606 can be implemented by special purpose logic circuitry, e.g., an FPGA (field programmable gate array) or an ASIC (application-specific integrated circuit). For example, the processor 606 can include a collection of circuitry and logic instructions within an FPGA or ASIC. The processor 606 can also include, in addition to hardware, code that creates an execution environment for the computer program in question, e.g., code that constitutes processor firmware, a protocol stack, an operating system, or a cross-platform runtime environment.

In some implementations, the system 600 can be included within the display apparatus 611. For example, the backlight 608 can be the backlight used by the display apparatus 611 and the optical detection system can be a photodiode array included within the housing of the display apparatus 611. The system 600 can then be used any time during the life of the display to adjust the operating voltage of the display apparatus 611. This can help to ensure that the display apparatus 611 operates at a sufficient operating voltage even if some of the design parameters change over time.

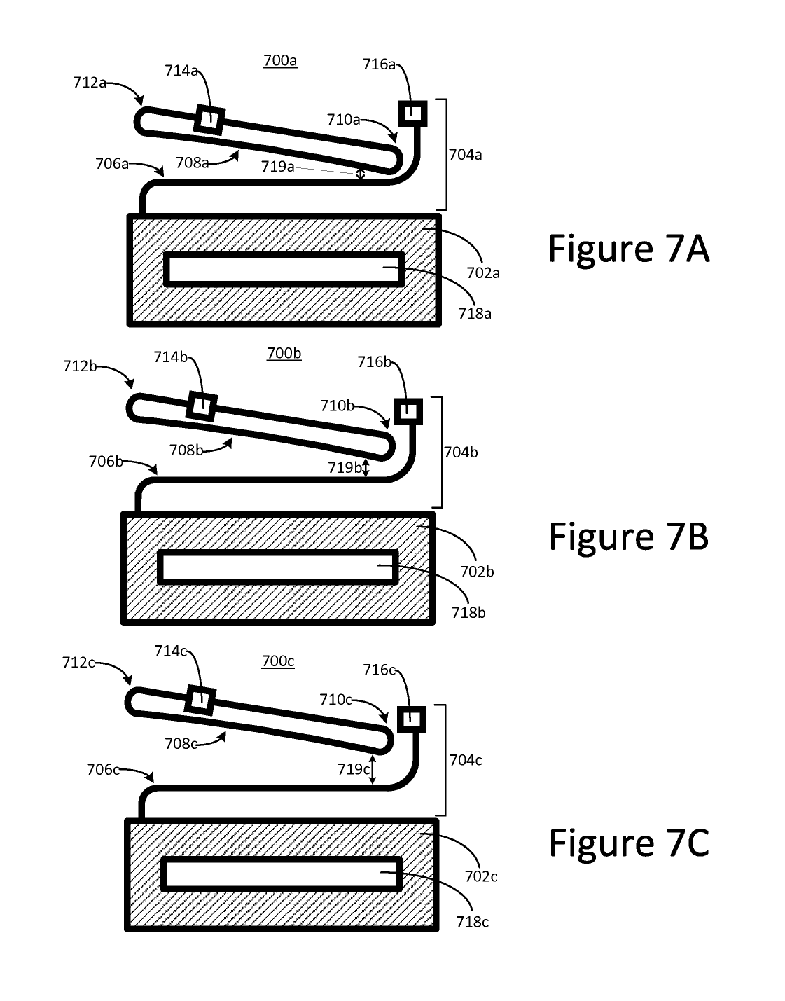

FIGS. 7A-7C show example optically inactive display elements 700a-700c having various tip gap separations 719a-719c. The optically inactive display elements 700a-700c are formed according to a common architecture. For example, the optically inactive display element 700a includes a shutter 702a and an actuator 704a. The actuator 704a is an electrostatic actuator including a load beam 706a that is fixed at one end to an edge of the shutter 702a and at another end to a load anchor 716a. The actuator 704a also includes a drive beam 708a. The drive beam 708a is shaped as a loop arranged at an angle with respect to the shutter 702a. A front end 710a (sometimes also referred to as the tip 710a) of the drive beam 708a is positioned closer to the load beam 706a than a rear end 712a of the drive beam 708a. A drive anchor 714a is positioned on a back portion of the looped drive beam 708a (i.e., the side facing away from the load beam 706a). The drive anchor 714a mechanically couples the drive beam 708a to an underlying substrate over which the shutter 702 and the actuators 704 are suspended. A load anchor 716a couples the load beam 706a to the underlying substrate. The load beam 706a extends along substantially the entire length of the drive beam 708a.

The optically inactive display elements 700b and 700c include components similar to those included in the optically inactive display element 700a, and like reference numerals refer to like components. The primary differences between the three optically inactive display elements 700a-700c are the separation distances between the front ends 710 of their respective drive electrodes 708 and their respective load beams 706. This separation distance is referred to as the tip gap. For example, the tip gap 719a of the optically inactive display element 700a is smaller than the tip gap 719b of the optically inactive display element 700b. The tip gap 719b of the optically inactive display element 700b is smaller than the tip gap 719c of the optically inactive display element 700c. For illustrative purposes, reference is made primarily to the optically inactive display element 700a in describing its functionality below, but the principles discussed apply equally to the optically inactive display elements 700b and 700c as well.

The position of the shutter 702a is controlled by the actuator 704a. For example, an actuation voltage can be applied across the drive beam 708a and the load beam 706a of the actuator 704a. The actuation voltage creates an electrostatic force that tends to draw the drive beam 708a and the load beam 706a together. Because the drive beam 708a is fixed to the substrate by the drive anchor 714a, the electrostatic force causes the load beam 706a to move towards the drive beam 708a. As the load beam 706a moves, the shutter 702a also moves toward the drive beam 708a while remaining substantially parallel to the underlying substrate, because the load beam 706a is fixed to the edge of the shutter 702. When the actuation voltage is removed, the load beam 706a can move back to its relaxed position. Therefore, by selectively applying actuation voltages to actuator 704a, the position of the shutter 702a can be controlled.

The shutter 702a includes an aperture 718a through which light can pass when the aperture 718a is aligned with an aperture formed in the underlying substrate. To ensure that the optically inactive display element 700a does not permit light to escape from the display apparatus in which it is formed, a light blocking layer may be formed directly over the optically inactive display element 700a. Thus, by modulating the position of the shutter 702a using the actuators 704, the amount of light that is permitted to pass through the shutter 702a can be controlled, but the optically inactive display element 700a can remain optically dark regardless of the position of the shutter 702a.

The actuation voltage required to move the shutter 702a towards the actuator 704a can be partially based on the separation distance 719a between the load beam 706a and the drive beam 708a. In particular, the separation distance 719a between the tip of the load beam 706a and the drive beam 708a can impact the actuation voltage, with a larger separation distance typically resulting in a larger actuation voltage. Therefore, an optically inactive display element having a larger tip gap, such as the optically inactive display element 700c, may require a higher actuation voltage than an optically inactive display element having a smaller tip gap, such as the optically inactive display element 700a. As such, the optically inactive display elements 700a-700c having different tip gaps 719a-719c should exhibit varying voltage responses. By manufacturing the optically inactive display elements 700a-700c with differing tip gaps 719a-719c and measuring the voltage responses for a given operating voltage or range of operating voltages, a required operating voltage for a display in which the optically inactive display elements 700a-700c are incorporated can be determined.

In some implementations, the variation of the tip gaps 719a-719c can be selected to approximate the variation expected to occur within a set of image-forming display elements that are manufactured to have nominally identical tip gaps. For example, the tip gap 719b of the optically inactive display element 700b may be selected to be the same as the nominal tip gap for the image-forming display elements. The tip gap 719a of the optically inactive display element 700a may be selected to be slightly smaller, and the tip gap 719c of the optically inactive display element 700c may be selected to be slightly larger, such that the optically inactive display elements 700a-700c incorporate tip gaps 719a-719c that span the range of tips gaps expected to occur within the image-forming display elements due to imperfections in the deposition and etching processes discussed above.

In some implementations, a display apparatus may include more than three optically inactive display elements having different tip gaps, in order to generate a larger data set of the actuation responses for display elements incorporating different tip gaps. Other optically inactive display elements can be formed with variations in other design parameters, as discussed further below.

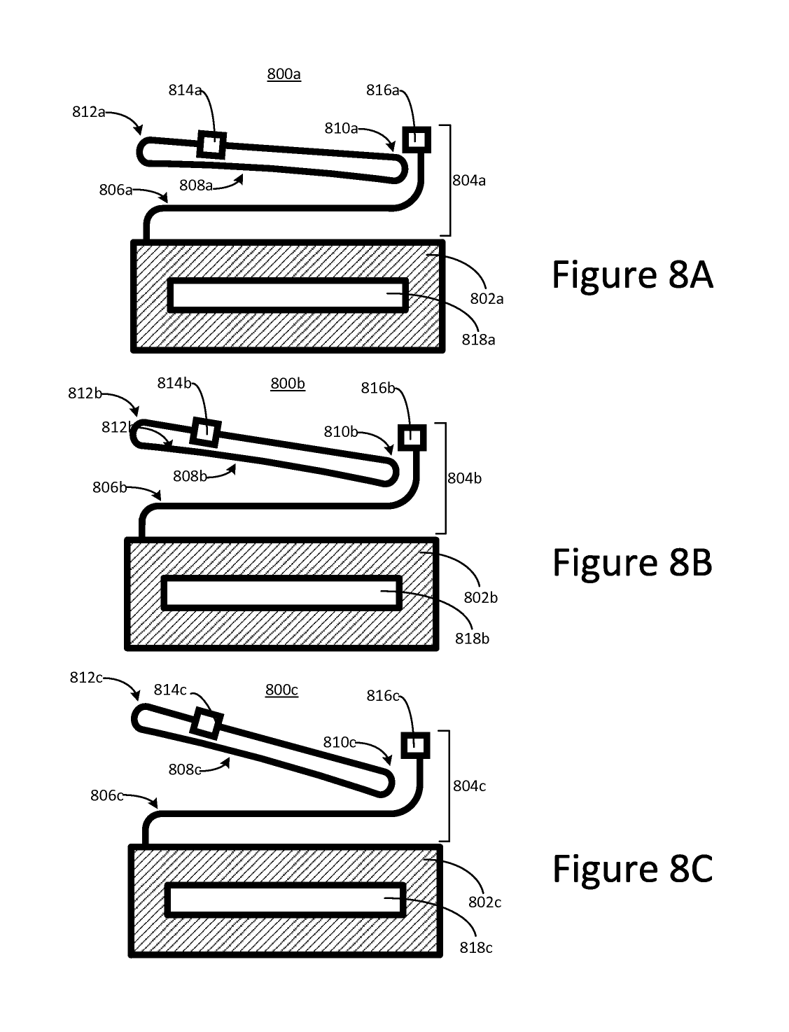

FIGS. 8A-8C show example optically inactive display elements 800a-800c having drive beams 808a-808c positioned at various angles. The optically inactive display elements 800a-800c have a general architecture that is similar to that of the optically inactive display element 700a shown in FIG. 7A. For example, the optically inactive display element 800a includes a shutter 802a having an aperture 818a. The shutter 802a is coupled to an electrostatic actuator 804a. The actuator 804a includes a load beam 806a coupled to a respective edge of the shutter 802a at one end and to a load anchor 816a at the other end. The actuator 804a also includes a drive beam 808a. The optically inactive display elements 800b and 800c include similar features, with like reference numerals referring to like elements.

In contrast to the optically inactive display elements 700a-700c shown in FIGS. 7A-7C, the optically inactive display elements 800a-800c all have substantially the same tip gap. However, the optically inactive display elements 800a-800c have differing angles for their corresponding drive beams 808a-808c. As shown, the angle of the drive beam 808a relative to the load beam 806a is smaller than the angle of the drive beam 808b relative to the load beam 806b, and the angle of the drive beam 808b relative to the load beam 806b is smaller than the angle of the drive beam 808c relative to the load beam 806c. The other design parameters of the optically inactive display elements 800a-800c are substantially the same.

In some implementations, the angle of the drive beams 808a-808c relative to the respective load beams 806a-806c can impact the actuation voltage for each optically inactive display element 800a-800c. For example, the differing angles result in differing separation distances between the drive beams 808a-808c and the respective load beams 806a-806c along the lengths of the drive beams 808a-808c and the load beams 806a-806c. Larger separation distances typically require higher voltages for actuation. Therefore, a drive beam arranged at a larger angle, such as the drive beam 808c of the optically inactive display element 800c, may lead to a higher required actuation voltage than a drive beam arranged at a smaller angle, such as the drive beam 808a of the optically inactive display element 800a. As such, the optically inactive display elements 800a-800c whose drive beams 808a-808c are arranged at different angles should exhibit varying voltage responses.

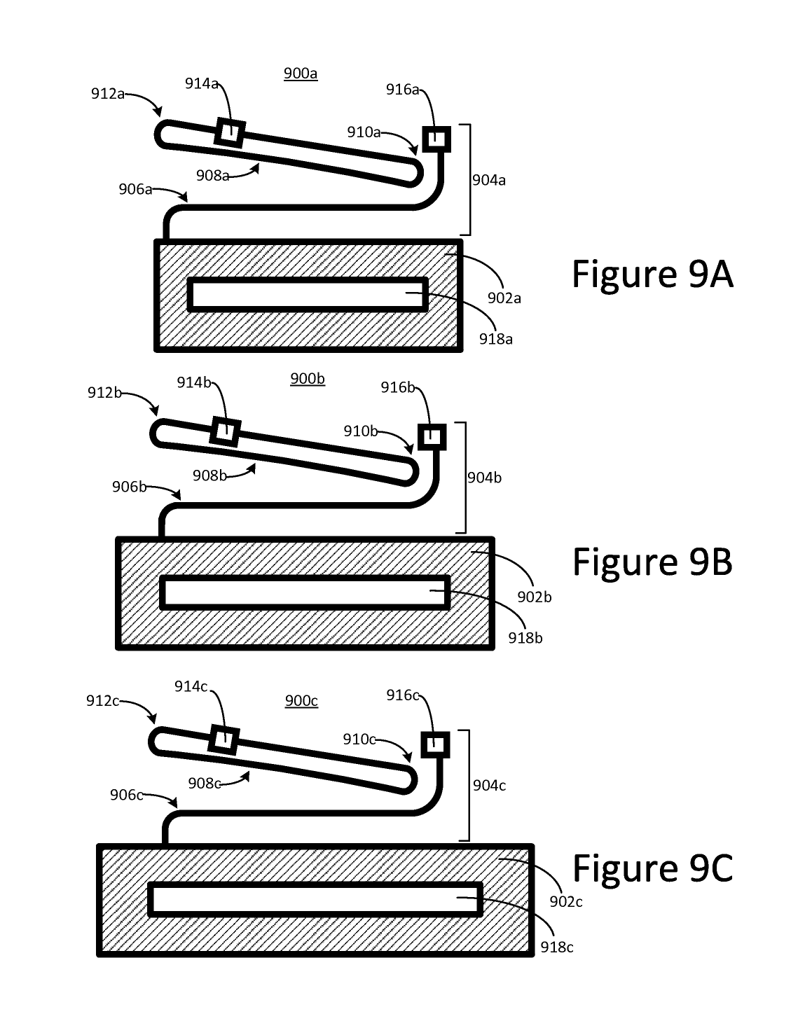

FIGS. 9A-9C show example optically inactive display elements having shutters of various widths. The optically inactive display elements 900a-900c have a general architecture that is similar to that of the optically inactive display element 700a shown in FIG. 7A. For example, the optically inactive display element 900a includes a shutter 902a having an aperture 918a. The shutter 902a is coupled to an electrostatic actuator 904a. The actuator 904a includes a load beam 906a coupled to a respective edge of the shutter 902a at one end and to a load anchor 916a at the other end. The actuator 904a also includes a drive beam 908a. The optically inactive display elements 900b and 900c include similar features, with like reference numerals referring to like elements.

Rather than differing tip gaps or drive beam angles, the optically inactive display elements 900a-900c have differing widths for their respective shutters 902a-902b. As shown, the width of the shutter 902a is smaller than the width of the shutter 902b, and the width of the shutter 902b is smaller than the width of the shutter 902c. The other design parameters of the optically inactive display elements 900a-900c are substantially the same.

In some implementations, a display apparatus incorporating the optically inactive display elements 900a-900c can be filled with a substantially incompressible fluid, such as an oil, that surrounds the shutters 902a-902c of the optically inactive display elements 900a-900c. As the shutters 902a-902c move in response to an actuation voltage, they can experience resistance exerted by the fluid. This resistance can vary according to the size of the shutters 902a-902c. Therefore, a shutter having a larger size, such as the shutter 902c of the optically inactive display element 900c, may experience greater fluid resistance than a shutter having a smaller size, such as the shutter 900a of the optically inactive display element 900a. As such, the optically inactive display elements 900a-900c having different sized shutters 902a-902c should exhibit varying voltage responses.

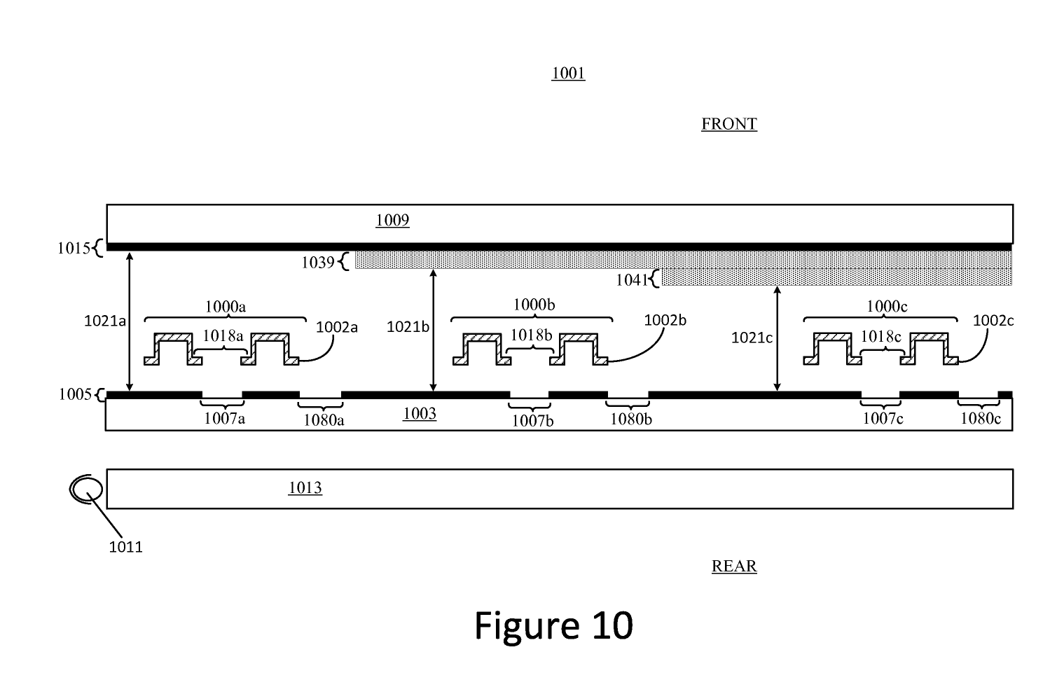

FIG. 10 shows a cross-sectional view of an example display apparatus 1001 including three optically inactive display elements 1000a-1000c having various cell gaps. The cell gap for a display element is defined as the distance between a front substrate positioned in front of the display element and a rear substrate positioned behind the display element. The optically inactive display elements 1000a-1000c are substantially similar to the optically inactive display elements 700a shown in FIG. 7A, and like reference numerals refer to like elements. For illustrative purposes, not all of the components of the optically inactive display elements 1000a-1000c are shown.

The optically inactive display elements are formed over the rear substrate 1003. A light blocking layer 1005 covers the rear substrate 1003. First apertures 1007a-1007c and second apertures 1080a-1080c, each associated with a respective one of the optically inactive display elements 1000a-1000c, are formed in the light blocking layer 1005. A front substrate 1009 is positioned in front of the optically inactive display elements 1000a-1000c and the rear substrate 1003. A light source 1011 and a light guide 1013, together forming a backlight, are positioned behind the rear substrate 1003. To ensure that the optically inactive display elements 1000a-1000c do not emit light, a light-blocking layer 1015 is formed on the rear surface of the front substrate 1009.

To achieve differing cell gaps, a first layer of material 1039 is deposited over the light blocking layer 1015 in the region above the shutters 1002b and 1002c, and a second layer of material 1041 is deposited over the first layer of material 1039 in the region above the shutter 1002c. The optically inactive display elements 1000a-1000c therefore have different cell gaps 1021a-1021c. As shown, the cell gap 1021a of the shutter 1002a is greater than the cell gap 1021b of the shutter 1002b, and the cell gap 1021b of the shutter 1002b is greater than the cell gap 1021c of the shutter 1002c. The other design parameters of the optically inactive display elements 1000a-1000c are substantially the same.

As discussed above, a display incorporating the optically inactive display elements 1000a-1000c can be filled with a substantially incompressible fluid. The cell gap can impact the actuation speed and actuation time in the presence of such a fluid. For example, the fluid is more easily displaced by an actuating shutter when the cell gap is larger, because there is more space into which the fluid can be moved by the shutter. Therefore, the shutter 1002a will likely actuate at a lower voltage than the shutter 1002b, and the shutter 1002b will likely actuate at a lower voltage than the shutter 1006c. As such, the optically inactive display elements 1000a-1000c having different cell gaps should exhibit varying voltage responses.

In some implementations, an optical detection system such as the optical detection system 610 shown in FIG. 6A may be positioned on the front side of the front substrate 1009. The optical detection system and the materials used for the various components of the optically inactive display elements 1000a-1000c may be selected to allow the optical detection system to measure the voltage responses of the optically inactive display elements 1000a-1000c while still preventing visible light from escaping from the display apparatus 1001. For example, the backlight 1011 may be configured to emit a broad spectrum of light, including wavelengths that are outside the visible range of the human visual system. The shutters 1002a-1002c of the optically inactive display elements 1000a-1000c can be formed from a material that blocks substantially all light (i.e., visible and invisible wavelengths), while the light blocking layer 1015 can be formed from a material that blocks visible light but is transparent to certain light wavelengths that are not visible to humans (e.g., infrared light). The optical detection system can then be configured to detect the invisible light that passes through the light blocking layer 1015. For example, the shutters 1002a-1002c can be formed from aluminum, which is substantially opaque to visible light and infrared light, while the light blocking layer 1015 can be formed from silicon, which blocks visible light but is substantially transparent to infrared light. An infrared optical detection system could then be used to determine the voltage responses of the optically inactive display elements 1000a-1000c.

In some other implementations, the voltage responses of the optically inactive display elements 1000a-1000c can be measured before the light blocking layer 1015 is formed. Alternatively, the optical detection system may be positioned behind the rear substrate 1005 and configured to measure the voltage responses of the optically inactive display elements 1000a-1000c by detecting the reflection of light off of the shutters 1002a-1002c.

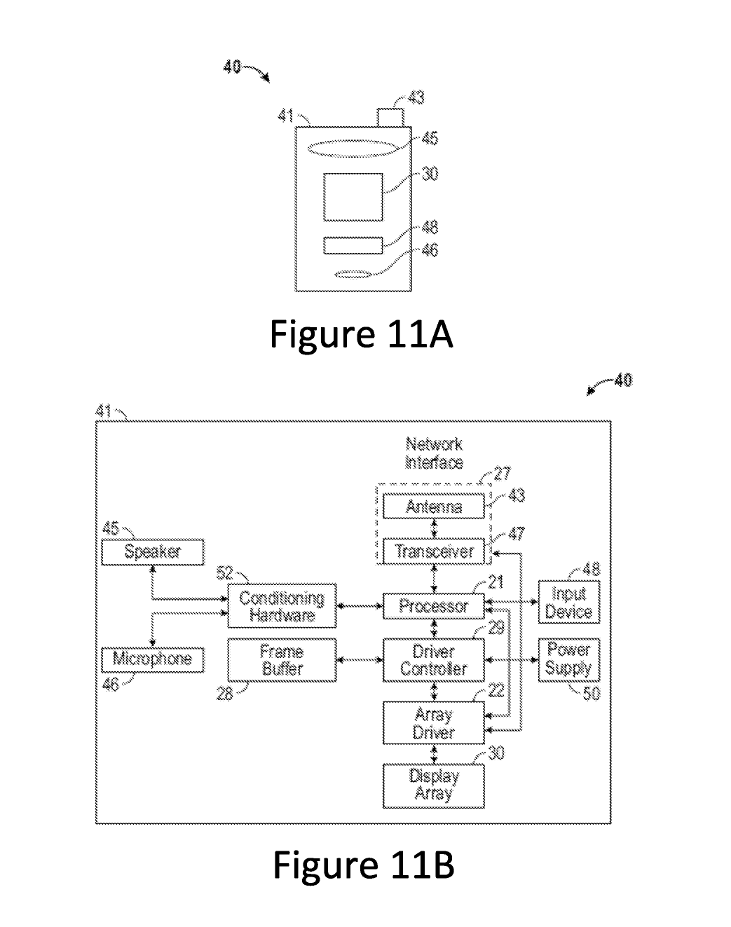

FIGS. 11A and 11B show system block diagrams of an example display device 40 that includes a plurality of display elements. The display device 40 can be, for example, a smart phone, a cellular or mobile telephone. However, the same components of the display device 40 or slight variations thereof are also illustrative of various types of display apparatus such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 11B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 11A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a first substrate;
an array of image-forming display elements positioned on the first substrate to form an image-forming region, each image-forming display element including a shutter;
a plurality of optically inactive display elements positioned on the first substrate, each optically inactive display element including a shutter, wherein:
each image-forming display element and each optically inactive display element has a common architecture;
each image-forming display element is substantially identical to each other image-forming display element;
each optically inactive display element has at least one design parameter that differs from a corresponding design parameter of the image-forming display elements; and
the at least one design parameter of a first optically inactive display element differs from the at least one design parameter of a second optically inactive display element.

2. The apparatus of claim 1, wherein:
each image-forming display element and each optically inactive display element further comprises at least one actuator including a load beam attached to its respective shutter and a drive beam.

3. The apparatus of claim 2, wherein for each optically inactive display element, the at least one design parameter that differs from a design parameter of the image-forming display elements is a separation distance between the respective load beam and a distal end of the respective drive beam.

4. The apparatus of claim 2, wherein for each optically inactive display element, the at least one design parameter that differs from a design parameter of the image-forming display elements is an angle of the respective drive beam relative to the respective load beam.

5. The apparatus of claim 2, wherein for each optically inactive display element, the at least one design parameter that differs from a design parameter of the image-forming display elements is a length of the respective drive beam.

6. The apparatus of claim 2, wherein for each optically inactive display element, the at least one design parameter that differs from a design parameter of the image-forming display elements is a length of the respective load beam.

7. The apparatus of claim 1, wherein:
each image-forming display element and each optically inactive display element further comprises a respective transistor; and
for each optically inactive display element, the at least one design parameter that differs from a design parameter of the image-forming display elements is a channel width of the respective transistor.

8. The apparatus of claim 1, wherein for each optically inactive display element, the at least one design parameter that differs from a design parameter of the image-forming display elements is a width of the respective shutter.

9. The apparatus of claim 1, further comprising a second substrate opposed to the first substrate, wherein for each optically inactive display element, the at least one design parameter that differs from a design parameter of the image-forming display elements is a separation distance between a surface of the respective shutter and a surface of the second substrate.

10. The apparatus of claim 1, further comprising at least one of a photodiode and a camera capable of measuring a response time to an applied voltage for the respective shutters of each optically inactive display element.

11. The apparatus of claim 1, further comprising a controller configured to select an operating voltage for the apparatus.

12. The apparatus of claim 11, wherein the controller is further configured to select the operating voltage for the apparatus based on a measured response to a single voltage applied to each optically inactive display element.

13. The apparatus of claim 11, wherein the controller is further configured to select the operating voltage for the apparatus based on a measured response to a range of voltages applied to each optically inactive display element.

14. The apparatus of claim 1, wherein the optically inactive display elements are positioned outside of the image-forming region.

15. The apparatus of claim 1, wherein the optically inactive display elements are positioned within the image-forming region.

16. A system for calibrating a display apparatus, the system comprising:
a controller configured to transmit to each of a plurality of optically inactive display elements positioned over a display element substrate a signal causing a shutter associated with each of the plurality of optically inactive display elements to move into a closed position;
a backlight positioned behind the display element substrate; and
an optical detection system configured to measure a response time for each of the optically inactive display elements.

17. The system of claim 16, wherein the optical detection system comprises at least one of a photodiode or a camera.

18. The system of claim 16, wherein the display element substrate further comprises:
an array of image-forming display elements positioned on the first substrate to form an image-forming region, wherein the plurality of optically inactive display elements is positioned outside of the image-forming region and wherein:
each image-forming display element and each optically inactive display element has a common architecture;
each image-forming display element is substantially identical to each other image-forming display element;
each optically inactive display element has at least one design parameter that differs from a corresponding design parameter of the image-forming display elements; and
the at least one design parameter of a first optically inactive display element differs from the at least one design parameter of a second optically inactive display element

19. The system of claim 16, wherein the controller is further configured to select an operating voltage for the apparatus based on a measured response to a range of voltages applied to each optically inactive display element.

20. The system of claim 16, further comprising a memory element configured to store a lookup table indicating operating voltages suitable for a range of measured response times of optically inactive display elements.
